(19) United States
(12) Patent Application Publication
(10) Pub. No.: US 2012/0074818 A1
(43) Pub. Date: Mar. 29, 2012

(54) SYSTEMS HAVING INTEGRATED MECHANICAL RESONATING STRUCTURES AND RELATED METHODS

(75) Inventors: Matthew J. Crowley, Milton, MA (US); Guiti Zoliagharkhani, Brighton, MA (US); Klaus Juergen Schoepf, Chandler, AA (US)

(73) Assignee: Sand9, Inc., Cambridge, MA (US)

(21) Appl. No.: 13/191,851

(22) Filed: Jul. 27, 2011

Related U.S. Application Data
(60) Provisional application No. 61/368,216, filed on Jul. 27, 2010.
(60) Provisional application No. 61/368,218, filed on Jul. 27, 2010.
(60) Provisional application No. 61/368,224, filed on Jul. 27, 2010.
(60) Provisional application No. 61/368,227, filed on Jul. 27, 2010.

(51) Int. Cl. H01L 41/053

(52) U.S. Cl. 310/348

(57) ABSTRACT

Devices including integrated components are described. The components may be integrated by being formed on a single substrate. The components may be integrated by being formed on separate chips within a multi-chip module. The components being integrated may include mechanical resonating structures, which in some instances may be piezoelectric mechanical resonating structures.

### RELATED APPLICATIONS

This application claims priority under 35 U.S.C. §119(e) to U.S. provisional application No. 61/368,216, filed Jul. 27, 2010 under Attorney Docket No. G0766.70022US00 and entitled “Integrated On-Chip GPS and Inertial Navigation System,” the entire contents of which is incorporated herein by reference.

This application also claims priority under 35 U.S.C. §119(e) to U.S. provisional application No. 61/368,218, filed Jul. 27, 2010 under Attorney Docket No. G0766.70023US00 and entitled “Integrated On-Chip Microelectromechanical Systems (MEMS) Radio Frequency Components In Transceivers,” the entire contents of which is incorporated herein by reference.

This application also claims priority under 35 U.S.C. §119(e) to U.S. provisional application No. 61/368,224, filed Jul. 27, 2010 under Attorney Docket No. G0766.70024US00 and entitled “Monolithically Integrated Piezoelectric Location Awareness Device,” the entire contents of which is incorporated herein by reference.

This application also claims priority under 35 U.S.C. §119(e) to U.S. provisional application No. 61/368,227, filed Jul. 27, 2010 under Attorney Docket No. G0766.70025US00 and entitled “Wafer Level Stacking Of MEMS Resonator With IC Wafer,” the entire contents of which is incorporated herein by reference.

### BACKGROUND

1. Field

The present application relates to systems having integrated mechanical resonating structures, and related methods.

2. Related Art

Global positioning system (GPS) receivers utilize resonating elements to provide a reference signal. GPS receivers are sometimes used in combination with other devices that also utilize resonating elements. Conventionally, the resonating elements of the GPS receiver and any combined devices are not integrated.

### SUMMARY

According to one aspect, a system is provided, comprising a global positioning system (GPS) receiver having a first mechanical resonating structure, and an inertial navigation system (INS) comprising a second mechanical resonating structure. The first mechanical resonating structure and second mechanical resonating structure are integrated.

Further aspects are described below.

### BRIEF DESCRIPTION OF DRAWINGS

Various aspects and embodiments of the technology will be described with reference to the following figures. It should be appreciated that the figures are not necessarily drawn to scale. Items appearing in multiple ones of the figures are indicated by the same or a similar reference number in all the figures in which they appear.

FIG. 1 is a block diagram of a GPS receiver.

FIG. 2 illustrates a non-limiting example of an integrated navigation system including a GPS device and an inertial navigation system, according to one embodiment.

FIGS. 3A and 3B illustrate a perspective view and a cross-sectional view, respectively, of a resonating structure as may be used according to various aspects described herein.

FIG. 4 illustrates a non-limiting example of a multi-chip module according to one embodiment.

FIGS. 5A and 5B illustrate a cross-sectional view and a top view, respectively, of a membrane formed on a substrate and suitable for forming a micromechanical resonating structure, according to one non-limiting embodiment.

FIGS. 6A and 6B illustrate a cross-sectional view and a top view, respectively, of an oxidized membrane formed on a substrate and suitable for forming a micromechanical resonating structure, according to another non-limiting embodiment.

FIG. 7 illustrates a cross-sectional view of a structure including multiple membranes formed on a substrate and each suitable for forming a micromechanical resonating structure, according to another non-limiting embodiment.

FIGS. 8A and 8B illustrate a cross-sectional view and a top view, respectively, of trench patterns which may be used to form the structure of FIG. 7, according to one non-limiting embodiment.

FIG. 9 illustrates a non-limiting example of two micromechanical resonating structures monolithically integrated on the same substrate and having different thicknesses, according to one non-limiting embodiment.

FIG. 10 illustrates a device wafer bonded to a cap wafer, according to one non-limiting embodiment.

FIG. 11 illustrates a transceiver which may utilize integrated components, according to one non-limiting embodiment.

### DETAILED DESCRIPTION

Applicants describe herein devices and systems including two or more integrated mechanical resonating structures. In a non-limiting example, the mechanical resonating structures may be microelectromechanical (MEMS) resonating structures, and may be integrated either by being formed on separate semiconductor chips within a multi-chip module or by being formed on the same semiconductor chip (e.g., monolithically integrated). One of the mechanical resonating structures may be part of a GPS device (e.g., a GPS receiver) while a second one of the mechanical resonating structures may be part of a second device, such as an inertial navigation system (INS), a transceiver, or any other suitable device. One or more of the MEMS resonating structures may be piezoelectric.

According to one aspect of the technology, a GPS device (such as a GPS receiver) is coupled to a second device (such as an INS), and each includes one or more mechanical resonating structures. The mechanical resonating structures may perform any suitable functions, such as providing reference signals, operating as sensors (e.g., accelerometers, gyroscopes, pressure sensors, compasses, etc.), serving as filters (e.g., radio frequency (RF) filters, intermediate frequency (IF) filters, or any other suitable type of filters), or may serve any other function(s). Two or more of the mechanical resonating structures may be integrated, which may provide various benefits. According to a first non-limiting embodiment, the two or more mechanical resonating structures may be integrated within a multi-chip module, though they may be formed on separate semiconductor chips. According to an alternative, the integrated mechanical resonating structures may be formed on a single semiconductor substrate (e.g., monolithically integrated on the substrate). In one embodiment, the mechanical resonating structures may be formed on a single MEMS wafer and may be capped with a cap wafer which may or may not include circuitry to be coupled to the resonating structures.

According to another aspect of the technology, a system includes multiple MEMS components, one or more of which may be integrated with each other. In one non-limiting embodiment, the system may include a transceiver having numerous components, such as filters, switches, a GPS receiver, and an INS, or any other suitable components. Multiple ones of the components may be implemented as MEMS components, for example utilizing MEMS resonating structures. As a non-limiting example, a transceiver may include a MEMS-based filter, a MEMS-based switch, one or more MEMS reference clock generators, one or more accelerometers, one or more gyroscopes, or any other suitable components. Such components, conventionally formed and packaged as discrete components, may be integrated together, which may provide one or more of various benefits, such as space savings, improved performance, and ease of manufacturing, among others.

The aspects described above, as well as additional aspects, are described further below. These aspects may be used individually, all together, or in any combination of two or more, as the technology is not limited in this respect.

GPS devices, such as GPS receivers, are one example of devices which may include a mechanical resonating structure. For example, a mechanical resonating structure may be used as a reference oscillator or low frequency time reference to provide reference signals in the GPS receiver. An example is now described.

By way of explanation, the Global Positioning System is a space-based radio-navigation system that uses ranging signals broadcasted by multiple satellites to determine a precise position on or in proximity of the earth. Each satellite of the system continuously transmits a navigation message encoded at 50 bit/s and which contains three parts. The first part contains the GPS date and time (time-of-week and GPS week number) and the satellite's health status. The second part comprises high precision orbital information of the satellite referred to as ephemeris data. The third part contains the almanac data that contains information on coarse orbit and status of all satellites in the constellation, an ionospheric model, and the relationship of GPS derived time and Coordinated Universal Time (UTC).

Each satellite of the GPS system broadcasts signals using the two carrier frequencies 1575.42 MHz, also referred to as L1 frequency, and 1227.60 MHz, referred to as L2 frequency. Multiple frequencies are used for multiple reasons, including redundancy, resistance to jamming, and ability to measure the ionospheric delay error. A GPS system might use one, two, or more frequencies and it should be understood that the various aspects described herein applying to GPS receivers are not limited to using any particular number of frequencies.

To distinguish signals from different satellites despite the signals being sent on the same carrier frequency (e.g., the L1 carrier frequency) the GPS system uses a code division multiple access (CDMA) spread-spectrum technique. The navigation message, described above, is encoded with a 1023 bit long pseudo random (PRN) sequence that is unique for each satellite. This CDMA encoding is often referred to as coarse/acquisition code (C/A) or Gold code. The 1023 bit C/A sequence has a period of 1 millisecond and is transmitted continuously. Only 32 combinations of all possible combinations from the 1023 bit long code are used, and each satellite in the GPS system uses one unique code. Currently, only the L1 carrier is modulated with the C/A code, but additional frequencies may become available for civil applications in the future and it should be understood that those aspects described herein relating to GPS receivers are not limited to GPS receivers using any specific number of carrier frequencies. In addition to C/A code, a high precision military CDMA code (so-called P code) exists, which is not described in detail here.

The 1575.42 MHz carrier frequency (L1) is generated by an atomic clock in each satellite, providing utmost stability and accuracy. Large frequency fluctuations of the carrier frequency affect the achievable accuracy of the position computed by a GPS receiver based on the satellite ranging signal, and further affect the time it takes to compute a valid position, as well as influencing the critical signal level necessary to obtain a position estimate. The use of highly precise atomic clocks in the satellites minimizes these effects.

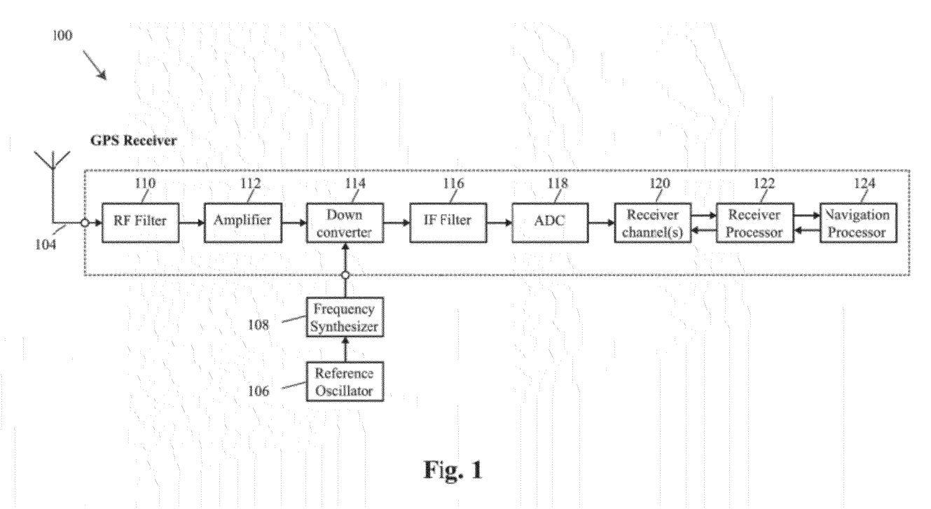

For a GPS receiver to obtain a position based on the received ranging signals of multiple satellites, the actual ranging signal has to be demodulated from the carrier. This demodulation requires a reference frequency on the receiver side to down-convert the GPS signal. A block diagram of a GPS receiver 100 is shown in FIG. 1. The antenna 104 will receive the GPS signals of all satellites available. The received signals are then filtered by a radiofrequency (RF) filter 110 and amplified by an amplifier 112. The amplified signals are then down-converted to an intermediate frequency of typically 1-20 MHz in down-converter 114. The down-conversion process requires a reference frequency which is generated by a frequency synthesizer 108 based on a reference oscillator 106. The intermediate frequency (IF) signals produced by down-converter 114 are then filtered in an IF filter 116 and converted to digital IF signals in an analog-to-digital converter (ADC) 118. The digital IF signals are then processed in one or more receiver channels 120. Each receiver channel includes two tracking loops, one for tracking the GPS carrier (a “carrier frequency tracking loop”) and one for tracking the GPS code (a “code tracking loop”) of a particular satellite. Advanced systems possess multiple receiver channels and therefore can track multiple satellites at the same time. Less sophisticated GPS units use multiplexing of multiple satellites and lock to one satellite at a time.

The carrier frequency tracking loop of a receiver channel 120 uses a phase locked loop (PLL) to lock a numerically controlled oscillator (NCO) to the digital IF signals from ADC 118 for a particular satellite, or rather to the satellite's C/A code. The frequency tracked by the PLL (f_{PLL}) incorporates any frequency variation of the satellite carrier due to Doppler shifts, fluctuations of the satellite's time base, frequency inaccuracies and drift of the local reference oscillator 106 introduced during the down-conversion by down-converter 114 and the analog-to-digital sampling process of ADC 118.

The code tracking loop of receiver channel 120 uses a delay-lock loop (DLL) to track the C/A code of the respective satellite for each receiver channel. The DLL uses the carrier replica signal from the NCO of the carrier frequency tracking loop. Tracking the delay of the C/A code in the DLL yields information about the time delay between the satellite and the receiver, basically by measuring the offset between the received PRN sequence and the internally generated 1023 bit C/A code replica. In combination with knowledge of the precise satellite time and position, the range of the GPS receiver from the satellite can be estimated. As the PRN code is transmitted over a period of 1 ms, one bit corresponds to 0.98 microseconds (10⁻³ s/1023), which, assuming the propagation of the satellite signal at the speed of light (299 792 458 m/s), corresponds to a distance of 293 meters. Currently available GPS receivers are able to detect the offset of rising and trailing edges of each bit to about 1% accuracy, which reduces the location uncertainty of 293 meters to less than 3 meters. The ranges for the satellite determined from the code tracking loop are referred to as pseudoranges. The expression of pseudorange refers to the range estimates being affected by a common offset. The delay obtained from the DLL tracking is affected by the clock error of the reference (or “local”) oscillator. Because the clock error is assumed to be constant over a short period of time, the error of the range estimates is assumed to be constant.

The receiver processor 122 in FIG. 1 handles the control loops for both the GPS carrier frequency tracking and the GPS code tracking. The navigation processor 124 uses the pseudorange estimates, described above, to solve for the unknowns of the position x, y, and z, and the clock timing error Δτ. Since there are four unknowns (x, y, z, Δτ), in general the GPS receiver will require at least the pseudoranges of four satellites to solve for the unknowns. By solving for the four unknowns, the receiver position can be established.

The accuracy of the frequency f_{PLL} tracked by the GPS carrier frequency tracking loop is affected by the GPS carrier-to-noise (C/N) ratio (white noise phase jitter), satellite clock phase jitter, receiver clock phase jitter, vibration-induced phase jitter, atmospheric phase jitter (all colored noise phase jitter), and dynamic stress due to sudden movement of the receiver. Depending on the application, the receiver clock phase jitter may be one of the most dominating effects.

The accuracy and stability of the frequency f_{PLL} determines the accuracy of the resulting calculated position of the GPS receiver and the robustness of the GPS receiver operation for very low C/N ratios. Robustness against cycle slip of the carrier tracking loop may impact performance of the GPS receiver, for example influencing the ability of the GPS receiver to maintain lock on the GPS carrier. Cycle slip can occur for numerous reasons including weak GPS signal strength (for example as may occur inside buildings, caves, and obstructions), strong phase fluctuations of the GPS signal (for example as may result from ionospheric fluctuations/scintillation effects, multi-path reflections in urban environment, etc.), dynamic stress, or any instability or malfunction of the satellite or receiver.

Conventionally, GPS receivers use temperature compensated crystal oscillators (TCXOs) or, for higher performance, oven controlled crystal oscillators (OCXOs) as the reference oscillator (e.g., as reference oscillator 106 in FIG. 1) instead of atomic clocks. Compared to atomic clocks, TCXOs and OCXOs are relatively inexpensive, miniature in size, and possess light weight. However, the reference oscillator may alternatively implement a MEMS resonator.

GPS devices may be used in combination with other devices. For example, GPS devices may be used in combination with other devices which augment the location determination functionality of the GPS devices, as a non-limiting example. As mentioned, GPS signal quality and strength, and therefore the performance of GPS receivers, is negatively impacted by multiple factors. Those factors include some weather conditions, attenuation of the GPS signals by buildings and objects, and multi-path signals and multi-path fading encountered in urban environments. Some such factors result in weak GPS signals or GPS signal outages, which cause inaccurate position readings from the GPS receivers. In addition, current GPS receivers require a long time to establish an initial position (referred to as “Time To First Fix” (TTFF)) and subsequent positions (referred to as “Time To Subsequent Fix” (TTSF)), which times are also extended by weak GPS signals and GPS signal outages. This limits the use of GPS in urban environments, buildings, tunnels, caves and under water.

One manner of addressing the shortcomings of GPS receivers in determining location is to use an integrated navigation system which augments the GPS data with data that is not susceptible to the same limitations as GPS data (e.g., augmenting GPS data with a complementary navigation system that can work in any environment, even those characterized by GPS signal outages). An inertial navigation system (INS) is an example of a suitable complementary navigation system.

Inertial navigation systems use inertial sensors such as accelerometers and gyroscopes to track the position and orientation of an object with respect to a reference point. The linear acceleration and rotation rate information provided by accelerometers and gyroscopes are integrated over time to deliver position and orientation information compared to the reference point, a technique referred to as Dead Reckoning (DR). A typical DR configuration may include one gyroscope for direction measurements and a 3-axis accelerometer, though other configurations are also possible. A magnetometer may also be included. INS can be used as a self-contained system without dependency on transmission and reception of external electrical signals, and may also be used as an assistance positioning system together with a global positioning system (GPS) device which provides location information. For example, the INS may provide location and orientation relative to the last valid GPS data point (i.e., the last valid GPS-determined location may serve as the reference point for the INS).

Even though integrated navigation systems combining GPS and DR techniques are already in use in some applications, such integrated navigation systems are not available for mass market portable consumer devices such as cellular phones, since no integrated navigation system combining GPS with an INS satisfies the basic preferences of light weight, small footprint, low power consumption and low cost associated with mass market portable consumer devices. Thus, currently, in most portable or handheld navigation devices, position is determined using only GPS data.

According to one aspect, an integrated system including a GPS device and an INS is described. The GPS and INS may be integrated on the same chip. The system may include MEMS-based components. For example, in some embodiments, the GPS device may include a MEMS-based reference oscillator, and the INS may include a MEMS-based gyroscope and a MEMS-based accelerometer. The MEMS-based gyroscope may be a single-axis or multi-axis MEMS gyroscope. The MEMS-based accelerometer may be a single-axis or multi-axis accelerometer.

In some embodiments, the GPS device includes one or more MEMS-based timing oscillators. For example, the timing oscillator may be a TCMO (temperature-compensated MEMS oscillator) and/or an OCMO (oven-controlled MEMS oscillator). Suitable timing oscillators have been described, for example, in: U.S. patent application Ser. No. 12/830,056, entitled “Methods and Apparatus for Tuning Devices Having Resonators”, filed Jul. 2, 2010 under Attorney Docket No. G0766.70019US00 and published as U.S. Patent Publication No. US-2010-0315170; U.S. Patent Application Ser. No. 61/363,759, entitled “Methods and Apparatus for Calibration and Temperature Compensation of Oscillators Having Mechanical Resonators”, filed Jul. 13, 2010 under Attorney Docket No. G0766.70021US00; and U.S. patent application Ser. No. 12/639,161 filed on Dec. 16, 2009 under Attorney Docket No. G0766.70006US01, entitled Mechanical Resonating Structures Including A Temperature Compensation Structure, and published as U.S. Patent Application Publication No. US-2010-0182102-A1 on Jul. 22, 2010, all of which are incorporated herein by reference in their entireties.

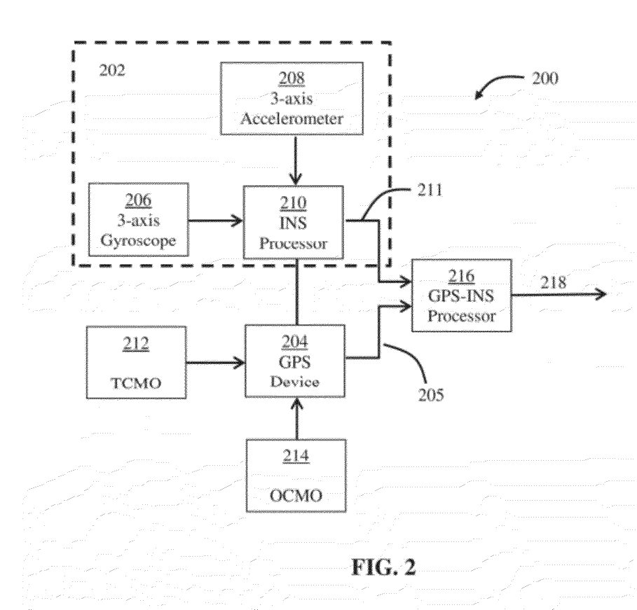

FIG. 2 illustrates a block diagram of a non-limiting example of an integrated navigation system 200 according to one embodiment. The integrated navigation system 200 includes an INS 202 and a GPS device 204. The INS 202 includes a 3-axis gyroscope 206, a 3-axis accelerometer 208, and an INS processor 210. The GPS device 204 receives a reference signal from one or both of a TCMO 212 and a OCMO 214.

In operation, the 3-axis gyroscope 206 and 3-axis accelerometer 208 provide their output signals to the INS processor 210. The INS processor 210 processes the received gyroscope and accelerometer signals to determine the position and orientation of the system 200 relative to a reference point (i.e., the changes in position and orientation). The position and orientation calculated by the INS processor 210 may be provided as output signal 211. The GPS device 204 provides an output signal 205 representing a GPS location.

The system 200 further comprises a GPS-INS processor 216 which processes the GPS data from the GPS device 204 (in the form of signal 205) and the output of the position and orientation data from the INS processor 210 (in the form of signal 211) to determine one or more of the absolute position (location), velocity, and altitude of the system 200, one or more of which quantities may then be provided by the GPS-INS processor 216 as an output signal 218.

According to one aspect of the technology, one or more mechanical resonating structures of an integrated navigation system, such as system 200 of FIG. 2, may be integrated. For example, referring to system 200, one or more of the 3-axis gyroscope 206, 3-axis accelerometer 208, TCMO 212, and OCMO 214 may be integrated. Integration of these components may be facilitated if they are MEMS components, and in some embodiments may be further facilitated if they are piezoelectric components.

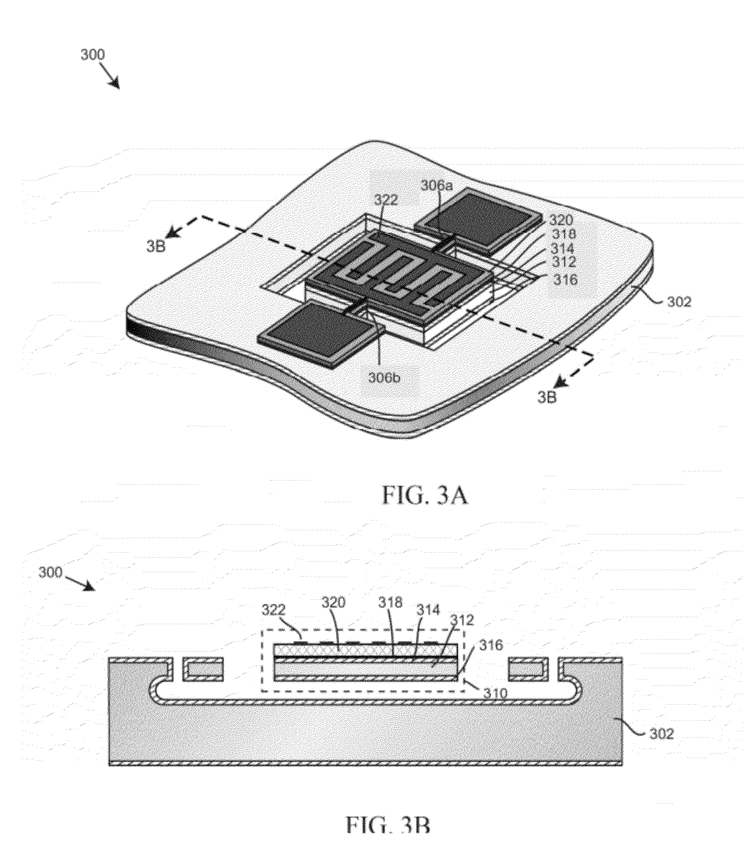

The integration of the mechanical resonating structures of an integrated navigation system may be performed in any suitable manner. To aid the understanding of the possibilities, a non-limiting example of a mechanical resonating structure is now described with respect to FIGS. 3A and 3B. The exemplary mechanical resonating structure shown is configured in a manner suitable to operate as a timing oscillator (for example, to provide a reference signal). Suitable alterations may be made to the illustrated design to operate in a desired manner, for example as a sensor (e.g., accelerometer, gyroscope, pressure sensor, etc.), a filter, or other device.

FIGS. 3A and 3B provide a perspective view and a more detailed cross-sectional view, respectively, of a device 300 including a mechanical resonating structure 310. As illustrated, the micromechanical resonating structure 310 (reference number shown in FIG. 3B) may include an active layer 320 (e.g., a piezoelectric layer, for example made of aluminum nitride, or any other suitable piezoelectric material), a bottom conducting layer 318 (e.g., a metal electrode), and one or more top electrodes 322. The active layer 320 may be actuated by applying a voltage/electric field thereto using top electrodes 322 (formed, for example, of a metal) and bottom conducting layer 318, which in some embodiments may be configured as a ground plane. Not all the illustrated components are required and other components may be included in some embodiments, as the illustration provides a non-limiting example of a mechanical resonating structure.

The micromechanical resonating structure 310 also includes a silicon layer 312, a silicon oxide layer 314 on the top surface of the silicon layer 312, and a silicon oxide layer 316 on the bottom surface of the silicon layer 312. The combination of silicon layer 312 and silicon oxide layers 314 and 316 may operate as a temperature compensation structure (a temperature compensation stack in this configuration) to compensate temperature-induced changes in the frequency of operation of mechanical resonating structure 310. For example, one manner in which to improve the temperature drift of silicon resonators is to add another layer of material on the silicon that, instead of softening with temperature, as is the case for silicon, hardens with temperature, as is the case for quartz and silicon dioxide. As disclosed in U.S. patent application Ser. No. 12/639,161 filed on Dec. 16, 2009 under Attorney Docket No. G0766.70006US01, entitled MECHANICAL RESONATING STRUCTURES INCLUDING A TEMPERATURE COMPENSATION STRUCTURE, and published as U.S. Patent Application Publication No. US-2010-0182102-A1 on Jul. 22, 2010, incorporated herein by reference in its entirety, a stack of two silicon oxide layers on the top and bottom of the silicon, respectively, can be implemented with a piezoelectric stack on either the top or bottom oxide (see, for example, FIGS. 3A and 3B). It should be appreciated that the silicon layer 312 may be formed of any suitable semiconductor material, and that silicon is a non-limiting example described herein for purposes of illustration. Similarly, layers 314 and 316 may be formed of any suitable material (e.g., other types of oxide), as silicon oxide is a non-limiting example. Also, as mentioned, not all the illustrated components are required and other components may be included in some embodiments, as the illustration provides a non-limiting example of a mechanical resonating structure.

The micromechanical resonating structure may be connected to a substrate 302 by two or more anchors. As shown in FIG. 3A, the micromechanical resonating structure 310 is connected to the substrate 302 by two anchors, 306a and 306b, which may be flexible in some embodiments. The number of anchors is not limiting, as any suitable number may be used. It should further be understood that the geometry of the anchors may be matched to a specific length to reduce the amount of acoustic energy transferred from the micromechanical resonating structure to the substrate. Suitable anchor structures that reduce stress and inhibit energy loss are described in U.S. patent application Ser. No. 12/732,575, filed Mar. 26, 2010 under Attorney Docket No. G0766.70005US01, published as U.S. Patent Publication No. 2010/0314969 and entitled “Mechanical Resonating Structures and Methods”, which is hereby incorporated herein by reference in its entirety.

As mentioned, various types and forms of mechanical resonating structures may be used with those aspects of the present technology relating to mechanical resonating structures, and FIGS. 3A and 3B provide only a non-limiting example. For example, the mechanical resonating structure may comprise or be formed of any suitable material(s) and may have any composition. According to some embodiments, the mechanical resonating structure may comprise a piezoelectric material (e.g., active layer 320). According to some embodiments, the mechanical resonating structure comprises quartz, LiNbO₃, LiTaO₃, aluminum nitride (AlN), or any other suitable piezoelectric material (e.g., zinc oxide (ZnO), cadmium sulfide (CdS), lead titanate (PbTiO₃), lead zirconate titanate (PZT), potassium niobate (KNbO₃), Li₂B₄O₇, langasite (La₃Ga₅SiO₁₄), gallium arsenide (GaAs), barium sodium niobate, bismuth germanium oxide, indium arsenide, indium antimonide), either in substantially pure form or in combination with one or more other materials. Moreover, in some embodiments in which the mechanical resonating structure comprises a piezoelectric material, the piezoelectric material may be single crystal material, although in other embodiments including a piezoelectric material the piezoelectric material may be polycrystalline.

The mechanical resonating structure may have any shape, as the shape illustrated in FIGS. 3A and 3B is a non-limiting example. For example, aspects of the technology may apply to mechanical resonating structures that are substantially rectangular, substantially ring-shaped, substantially disc-shaped, or that have any other suitable shape. As additional, non-limiting examples, the configuration of the mechanical resonating structure can include, for example, any antenna type geometry, as well as beams, cantilevers, free-free bridges, free-clamped bridges, clamped-clamped bridges, discs, rings, prisms, cylinders, tubes, spheres, shells, springs, polygons, diaphragms and tori. Moreover, the mechanical resonating structure may have one or more beveled edges. According to some embodiments, the mechanical resonating structure may be substantially planar. Moreover, geometrical and structural alterations can be made to improve quality (e.g., Q-factor, noise) of a signal generated by the mechanical resonating structure.

The mechanical resonating structures described herein may have any suitable dimensions, and in some embodiments may be micromechanical resonating structures. The mechanical resonating structure may have any suitable thickness, and in some embodiments the thickness may be related to a wavelength of a desired oscillation mode.

According to some embodiments, the mechanical resonating structures described herein have a large dimension (e.g., the largest of length, width, diameter, circumference, etc. of the mechanical resonating structure) of less than approximately 1000 microns, less than approximately 100 microns, less than approximately 50 microns, or any other suitable value. It should be appreciated that other sizes are also possible. According to some embodiments, the devices described herein form part or all of a microelectromechanical system (MEMS).

The mechanical resonating structures may have any desired resonance frequencies and frequencies of operation, and may be configured to provide output signals of any desired frequencies. For example, the resonance frequencies and/or frequencies of operation of the mechanical resonating structures, and the frequencies of the output signals provided by the mechanical resonating structures, may be between 1 kHz and 10 GHz. In some embodiments, they may be in the upper MHz range (e.g., greater than 100 MHz), or at least 1 GHz (e.g., between 1 GHz and 10 GHz). In some embodiments, they may be at least 1 MHz (e.g., 13 MHz, 26 MHz) or, in some cases, at least 32 kHz. In some embodiments, they may be in the range of 30 to 35 kHz, 60 to 70 kHz, 10 MHz to 1 GHz, 1 GHz to 3 GHz, 3 GHz to 10 GHz, or any other suitable frequencies. Thus, it should be appreciated that the listed frequencies are not limiting.

The mechanical resonating structures may be operated in various acoustic modes, including but not limited to Lamb waves, also referred to as plate waves including flexural modes, bulk acoustic waves, surface acoustic waves, extensional modes, translational modes and torsional modes. The selected mode may depend on a desired application of the mechanical resonating structure.

The mechanical resonating structure may be actuated and/or detected in any suitable manner, with the particular type of actuation and/or detection depending on the type of mechanical resonating structure, the desired operating characteristics (e.g., desired mode of operation, frequency of operation, etc.), or any other suitable criteria. For example, suitable actuation and/or detection techniques include, but are not limited to, piezoelectric techniques, electrostatic techniques, magnetic techniques, thermal techniques, piezoresistive techniques, any combination of those techniques listed, or any other suitable techniques. The various aspects of the technology described herein are not limited to the manner of actuation and/or detection.

According to some embodiments, the mechanical resonating structures described herein may be piezoelectric Lamb wave devices, such as piezoelectric Lamb wave resonators. Such Lamb wave devices may operate based on propagating acoustic waves, with the edges of the structure serving as reflectors for the waves. For such devices, the spacing between the edges of the resonating structure may define the resonance cavity, and resonance may be achieved when the cavity is an integer multiple of pitch p, where p=λ/2, with λ being the acoustic wavelength of the Lamb wave of interest, understanding that the device may support more than one mode of Lamb waves. However, it should be appreciated that aspects of the technology described herein apply to other types of structures as well, and that Lamb wave structures are merely non-limiting examples.

As should be appreciated from FIGS. 3A and 3B, in some embodiments suspended mechanical resonating structures are used, meaning that the mechanical resonating structure(s) may have one or more free sides. Referring to FIG. 3A, the mechanical resonating structure 310 has free ends and the sides are also substantially free, connected to the substrate 302 by anchors 306a and 306b.

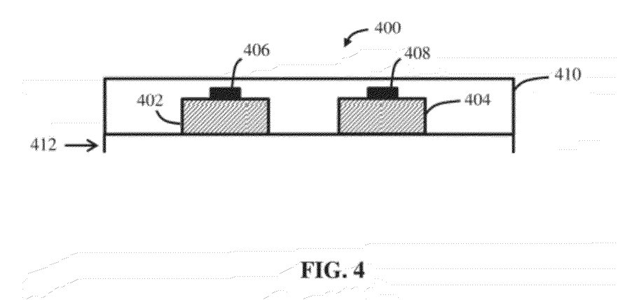

As mentioned, the mechanical resonating structures of the system 200 of FIG. 2 (e.g., the TCMO, OCMO, 3-axis gyroscope, and 3-axis accelerometer) may be integrated in various manners. According to a first alternative, two or more of the mechanical resonating structures, which may be of the same or similar type as that shown in FIGS. 3A-3B, may be formed on separate semiconductor chips (also referred to herein as semiconductor dies) and integrated within a multi-chip module. It may be preferred in some embodiments for all sub-components of the integrated navigation system to be integrated on multi-chip modules. A non-limiting example of the integration of multiple mechanical resonating structures within a multi-chip module is shown in FIG. 4.

As shown, the multi-chip module 400 includes chips 402 and 404, on which mechanical resonating structures 406 and 408 are formed, respectively. The chips 402 and 404 may be semiconductor chips, for example being semiconductor substrates (e.g., silicon substrates, though other materials are also possible). The chips 402 and 404 may include circuitry for connecting to the mechanical resonating structures 406 and 408. Mechanical resonating structures 406 and 408 may form any suitable components of an integrated navigation system. For example, mechanical resonating structure 406 may form at least part of a timing oscillator of a GPS receiver, for example providing a reference clock signal for the GPS receiver. Mechanical resonating structure 408 may form at least part of a 3-axis accelerometer for an INS. However, these are non-limiting examples, as it should be appreciated that the mechanical resonating structures 406 and 408 may form any suitable components of an integrated navigation system.

The multi-chip module 400 further comprises a package 410 in which the chips 402 and 404 are placed. The package may be any suitable package, including a plastic or ceramic package, as non-limiting examples. The package may have any suitable height and the mechanical resonating structures 406 and 408 may have dimensions which facilitate their placement within the package, for example having any of the dimensions previously listed herein with respect to FIGS. 3A and 3B. The package 410 may include leads 412 for making electrical connection to outside components.

It should be appreciated that FIG. 4 illustrates a non-limiting example of a multi-chip module integrating multiple components of an integrated navigation system. Alternatives are possible. For example, more components than those shown may be integrated within a single package. The components may be any suitable type of components, and in some instances are MEMS components to facilitate their integration. Any types of package may be used, and the package may have any suitable dimensions. In some instances, the package may have dimensions making it suitable for use in consumer handheld electronics, such as in cellular phones and PDAs.

In an alternative embodiment, two or more of the mechanical resonating structures of the system 200 may be integrated on the same semiconductor chip, for example being monolithically integrated. In some cases, it is preferred to integrate all the subcomponents of an integrated navigation system on a single chip. One manner in which such monolithic integration of multiple components of an integrated navigation system (or other system) may be accomplished is via the formation of membranes in a semiconductor substrate, with different membranes being incorporated into different mechanical resonating structures, as described in U.S. patent application Ser. No. 13/112,587, filed May 20, 2011 under Attorney Docket No. G0766.70020US01, and entitled “Micromechanical Membranes and Related Structures and Methods”, which is hereby incorporated herein by reference in its entirety. A non-limiting explanation is now provided.

Applicants have appreciated that silicon membranes suitable for forming micromechanical resonating structures may be formed using empty-space-in-silicon (ESS) principles, and furthermore that oxidation of such silicon membranes may then be performed to form temperature compensated structures. Thus, according to one aspect of the technology, silicon membranes suitable for formation of micromechanical resonating structures are formed from a silicon substrate. The dimensions of the membranes (e.g., thickness and area) may be selected to facilitate subsequent formation of a mechanical resonating structure having desired vibratory characteristics. The silicon membranes may be formed using ESS principles, as will be further described below, and in some embodiments may be oxidized to form temperature-compensated structures.

Applicants have further appreciated that ESS principles may be used to form multiple silicon membranes on the same silicon substrate, which may be used to form distinct micromechanical resonating structures, for instance to be used in different MEMS devices. Moreover, Applicants have appreciated that it may be beneficial in some instances to form, on the same substrate, silicon membranes of different thicknesses and/or with different oxide configurations, for example to provide devices incorporating such structures with different mechanical properties (e.g., vibratory properties).

Thus, according to another aspect of the technology, two or more silicon membranes are formed on the same silicon substrate and differ in one or more respects which may impact the vibratory characteristics of the membranes and thus the vibratory characteristics of resonating structures formed from the membranes. According to one such aspect, two or more of the silicon membranes may differ in their thicknesses, which therefore may result in the membranes exhibiting different vibratory characteristics. According to another such aspect, differing oxide configurations may be formed with respect to two or more of the silicon membranes. The oxide configurations may differ in terms of the presence or absence of oxide, the location of oxide, and/or the thickness of oxide.

According to another aspect of the technology, multiple silicon membranes are formed on a silicon substrate using different trench patterns in conjunction with ESS principles. The trench patterns may differ in terms of the area of the openings of the trenches, the depths of the trenches, the aspect ratios of the trenches and/or the pitches of the trench patterns. Annealing of the silicon substrate after formation of the trenches may then result in silicon membranes of differing dimensions (e.g., different thicknesses), as a result of the differing trench patterns.

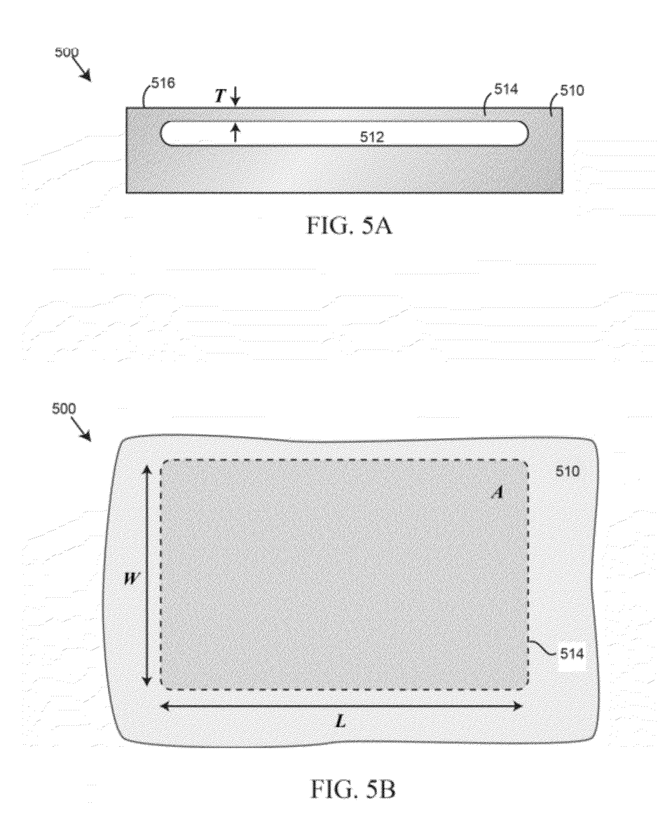

FIGS. 5A and 5B illustrate a cross-section and a top view, respectively, of an apparatus including a silicon membrane formed on a silicon substrate and suitable for formation of a mechanical resonating structure, according to one non-limiting embodiment. The apparatus 500 includes a substrate 510 in which a cavity 512 is formed. The substrate may be a silicon substrate, and in some embodiments may be a single crystal silicon substrate, though not all embodiments are limited in this respect, as other materials (e.g., glass) may alternatively be used. For example, the substrate may be a silicon-on-insulator (SOI) substrate, where either the device layer or the handle is used for membrane formation (e.g., membrane 514, described below). The substrate may be of any other suitable material and may comprise a single crystal layer composed of the same or other material or may comprise layers of different materials that could be single crystalline, polycrystalline or amorphous. The cavity 512 may be formed using ESS principles (i.e., formation of a trench in the substrate followed by an anneal), and may be an air cavity, a vacuum, or any other type of cavity. A membrane 514 is formed above, and defined by, the cavity 512, and is formed of the same material as that of which the substrate 510 is formed (e.g., silicon, and in some non-limiting embodiments, single crystal silicon, although other materials may alternatively be used). The membrane 514 is generally of the same crystallinity as the substrate 510 (e.g. single crystalline, polycrystalline, or amorphous) but this may be controlled to some degree by the details of the anneal process. The membrane 514 is outlined by the dashed line in FIG. 5B.

As mentioned, according to the present aspect, the membrane 514 may be suitable for formation of a mechanical resonating structure (e.g., by defining such a structure from the membrane), by proper shaping and dimensioning of the membrane. As shown in FIGS. 5A and 5B, the membrane 514 has a thickness T, and an area A defined by a length L and a width W (although it should be appreciated that the membrane is not limited to the illustrated rectangular shape). The dimensions T, L, and W may be selected such that membrane 514 is suitable for subsequent formation of a resonating structure having desired vibratory characteristics.

According to one non-limiting embodiment, to provide suitable vibratory characteristics, the membrane thickness T may be between approximately 1 and 20 microns. According to another embodiment, T may be between approximately 1 and 10 microns (e.g., 2 microns, 5 microns, etc.). According to one embodiment, T may be less than approximately three wavelengths of a resonance frequency of interest of a mechanical resonating structure to be formed from the membrane. According to some embodiments, the thickness T is less than approximately two wavelengths of a resonance frequency of interest of a resonating structure to be formed from the membrane. In still other embodiments, the thickness T may be less than approximately one wavelength of a resonance frequency of interest (e.g., less than approximately one wavelength of a resonant Lamb wave supported by a mechanical resonating structure to be formed from the membrane). Thus, it should be appreciated that the thickness of the membrane may determine or depend on the types of waves to be supported by a resonating structure to be formed from the membrane. For example, a given thickness may limit the ability of the resonating structure to support Lamb waves, or certain modes of Lamb waves. Thus, the thickness may be chosen dependent on the types and/or modes of waves desired to be supported by a mechanical resonating structure to be formed from the membrane. According to any of those embodiments described above, the thickness T may be substantially uniform (as shown in FIG. 5A), although not all embodiments are limited in this respect.

According to one embodiment, suitable vibratory characteristics of the membrane 514 may be provided by suitably selecting not only the thickness of the membrane, but also at least one other dimension (e.g., length or width) of the membrane. For instance, suitable selection of the ratio of the thickness (T) to the maximum dimension of L and W (i.e., the larger of L and W) may provide suitable vibratory characteristics of the membrane such that the membrane is suitable for formation of a mechanical resonating structure (e.g., a micromechanical resonating structure to be used in a MEMS oscillator). According to one non-limiting embodiment, the ratio of T to the larger of L and W is between 1:20 and 1:500 (e.g., 1:100, 1:200, 1:300, 1:400, etc.). According to an alternative embodiment, the ratio of T to the larger of L and W is between 1:20 and 1:100 (e.g., 1:20, 1:50, etc.). It should be appreciated that other ratios are also possible, and that those listed are provided for purposes of illustration and not limitation. It should also be appreciated that the rectangular shape of the membrane 514 illustrated in FIG. 5B is not limiting, and that other shapes are also possible, and therefore that, in some embodiments, the membrane may not be characterized by a substantially constant length and width. Even so, suitable dimensioning of the thickness T to the area A, regardless of the shape of the membrane, may provide suitable vibratory characteristics.

In any of those embodiments described above, or any other embodiments described herein in which the membrane has a length (L) and width (W), L and W may have any suitable values. For example, one or both of L and W may be less than approximately 1000 microns, less than approximately 100 microns (e.g., 75 microns, 60 microns, 50 microns, 40 microns, or any other value within this range), between approximately 50 microns and 200 microns, between approximately 70 microns and 120 microns, between approximately 30 microns and 400 microns, or have any other suitable values. Also, L and W need not be the same, and may differ by any suitable amounts, as the various aspects described herein as relating to membranes having dimensions L and W are not limited in this respect. According to some embodiments, L and W may be selected such that the area A is between approximately 110% and 300% (e.g., approximately 120%, approximately 150%, approximately 230%, approximately 250%, etc.) of the area of a mechanical resonating structure to be formed from the membrane, or in other embodiments between approximately 110% and 200% of the area of a mechanical resonating structure to be formed from the membrane, as described below.

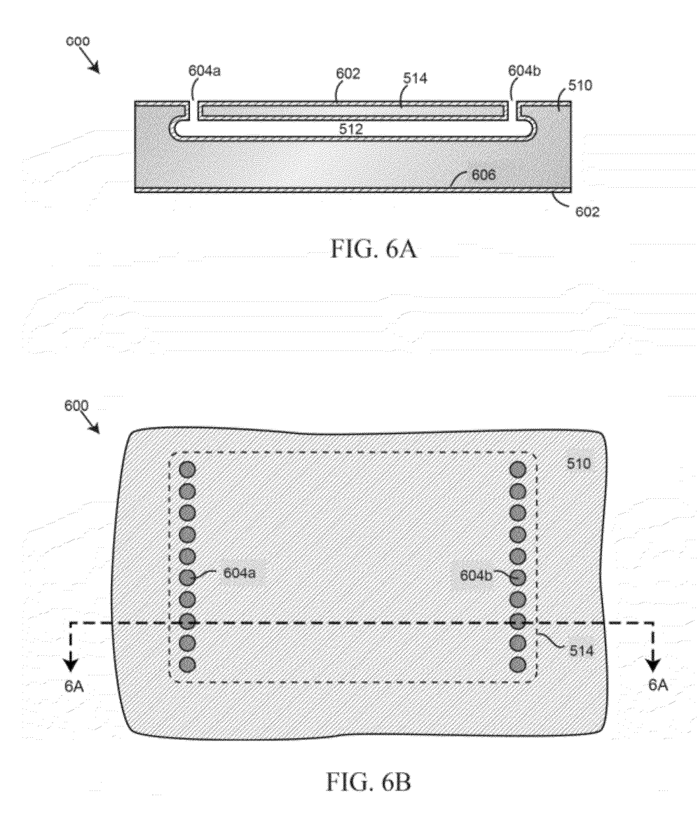

According to one aspect of the technology, a membrane (e.g., a single crystal silicon membrane) formed on a substrate (e.g., a single crystal silicon substrate) and suitable for formation of a mechanical resonating structure (e.g., a micromechanical resonating structure) is oxidized to provide a temperature compensated structure of the type(s) previously described with respect to U.S. patent application Ser. No. 12/639,161 (i.e., including silicon sandwiched between two layers of silicon oxide). A non-limiting example is illustrated in FIGS. 6A (cross section) and 6B (top view).

The illustrated apparatus 600 is similar to the apparatus 500 of FIG. 5A, with the addition of an oxide layer. As shown, the oxide layer 602 is formed on various surfaces of the structure, including on the membrane 514 (both the top and bottom surfaces of the membrane, in this non-limiting example), within the cavity 512 (i.e., on the walls of the cavity 512), and on the backside 606 of the substrate 510. The apparatus 600 includes access holes 604a and 604b, which are formed prior to formation of the oxide to provide access to the cavity 512 and therefore the backside (or bottom) of the membrane 514. By first forming the access holes 604a and 604b, the subsequent oxidation of the structure may produce the illustrated oxide configuration within the cavity 512 and on the bottom surface of the membrane 514.

The access holes may be of any suitable number and positioning, as well as each having any suitable size and shape, to facilitate formation of a desired oxide configuration (e.g., oxidizing the cavity 512 and/or the bottom of the membrane 514). FIG. 6B illustrates the device 600 in a top down view (with the oxide represented by the diagonal patterning), showing a non-limiting example of the size, shape, number, and arrangement of the access holes 604a and 604b. Variations are possible, and the various embodiments are not limited to the illustrated details.

To form the oxide illustrated in FIGS. 6A and 6B, after formation of the access holes, the silicon wafer or substrate may undergo thermal oxidation. Thermal oxidation may involve heating the wafer at a temperature typically between 850° C. and 1200° C., for example at 1100° C., in an atmosphere containing oxygen. Depending on the oxidizing conditions (e.g., temperature, wet or dry environment, etc.), pressure, and number and dimensions of the access holes, as well as the distance from the access holes to the center of the cavity, the thickness of the oxide on the bottom surface (or backside) of the membrane may be controlled to be substantially the same as or identical to the thickness of the oxide on the top surface of the membrane. According to some embodiments, the thickness of the oxide formed on the bottom surface of the membrane may be thinner than that formed on the top surface, for example, by between 2%-5%, between 2%-10%, between 10%-15%, or between 15%-20%, as non-limiting examples. The oxide thickness, however, may be accurately controlled and highly repeatable by use of a suitable access hole design.

As mentioned, the formation of the SiO₂—Si—SiO₂ multi-layer structure of apparatus 600 may provide temperature compensated functionality. Suitable selection of the ratio of the thickness of the silicon membrane to the total thickness of the silicon oxide layer(s) (e.g., the combined thickness of oxide layers on the top and bottom surfaces of the membrane) may provide for temperature compensation of a desired acoustic mode of vibration for a resonating structure formed from the membrane. For example, the ratio of the total thickness of the silicon oxide on the top and bottom surfaces of the membrane (when oxide is present on both the top and bottom surfaces of the membrane) to the silicon of the membrane may be between 1:0.1 and 1:10, between 1:0.5 and 1:3, between 1:0.75 and 1:1.25, or between 1:1 and 1:2, among other possible ratios. Thus, suitable values of the thickness of the oxide layer(s) may be determined from these ratios by reference to the suitable values of the thickness T of the membrane, described above.

Utilizing ESS principles with a subsequent oxidation step to form the oxidized structure illustrated in FIGS. 6A and 6B may be beneficial compared to alternative manners of forming a layer of silicon between two layers of silicon oxide, some of which alternatives may include use of a silicon-on-insulator (SOI) substrate. For example, using the techniques described herein, oxidation of the top and bottom surfaces of the membrane 514 may occur simultaneously (or substantially simultaneously), which may minimize or eliminate bowing of the membrane. In addition, formation of the silicon oxide within the cavity 512 and on the backside 606 of the substrate 510 may minimize or eliminate bowing of the substrate 510, thus facilitating further processing of the apparatus 600. In addition, the thickness of the membrane 514 may be controlled with high accuracy (e.g., to within ±0.02 microns) using the techniques described herein, a degree of control which may not be possible using SOI techniques with an SOI wafer (which may only have accuracy to ±0.5 microns). With the processes described herein, oxidation layers several micrometers thick, e.g. 0.1 μm to 3 μm, may be formed easily and with a very high degree of precision.

As mentioned, membranes of the type described herein may be utilized to form a mechanical resonating structure that may serve as part or all of a MEMS device, such as a MEMS oscillator. A non-limiting example is the mechanical resonating structure 310 of FIGS. 3A-3B, in which it should be appreciated that one or more of the components of the mechanical resonating structure 310 (e.g., components 312, 314, and 316, among others) may be formed using the techniques described with respect to FIGS. 5A-6B. According to one embodiment, the micromechanical resonating structure 310 may be formed by first forming the apparatus 600 of FIG. 6A and subsequently defining the micromechanical resonating structure from the membrane 514 (e.g., by lithography, etching or any other suitable technique). The mechanical resonating structure 310, as shown (after definition of the mechanical resonating structure from the membrane in those non-limiting embodiments in which the mechanical resonating structure is formed from a membrane), does not include a membrane, since the act of defining the micromechanical resonating structure from the membrane effectively alters the nature of the structure such that it is no longer a membrane. Formation of the micromechanical resonating structure 310 from a membrane, like that of FIG. 6A, may result in the micromechanical resonating structure being connected to a substrate by the anchors 306a and 306b. However, it should be appreciated that the micromechanical resonating structure 310 is not limited to being formed using a membrane, and that other methods of fabrication may be used.

It should be appreciated that those mechanical resonating structures described herein as being formed from membranes may have any suitable dimensions, and in some embodiments may have a thickness corresponding to the thickness of a membrane (plus any oxidation layers on the membrane) from which the mechanical resonating structure is defined.

As mentioned, Applicants have appreciated that in some instances it may be beneficial to form two or more membranes (e.g., single crystal silicon membranes) on the same substrate, such that the membranes may be incorporated into different devices (e.g., distinct oscillators). In some embodiments, the membranes may have different vibratory characteristics, such that the devices incorporating the membranes may have different vibratory characteristics, though in other embodiments multiple ones of the membranes may have substantially the same vibratory characteristics. Thus, according to another aspect, two or more silicon membranes may be formed on a silicon substrate, with the membranes differing in thickness. According to yet another aspect, two or more silicon membranes may be formed on a silicon substrate and differing oxide configurations may be formed with respect to the silicon membranes, such that differing mechanical characteristics may be provided.

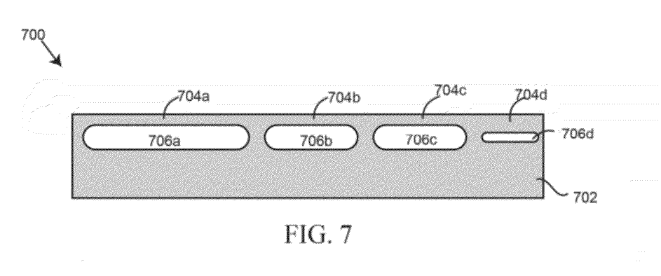

FIG. 7 illustrates a non-limiting example of an apparatus 700 including multiple silicon membranes formed on a silicon substrate 702 (although it should be appreciated that silicon is a non-limiting example of material). As shown, the apparatus includes four silicon membranes, 704a-704d, which are formed above, and defined by, respective cavities 706a-706d. As shown, the membranes do not overlap each other in this non-limiting example, as the cavities do not overlap each other (i.e., none of cavities 706a-706d overlies one of the other cavities in this non-limiting example). The cavities may be formed using ESS principles, by annealing of suitable trench formations. Each of the membranes 704a-704d may have dimensions (e.g., length, width, thickness) suitable to provide desired vibratory characteristics, such that devices having micromechanical resonating structures may be formed from each of the membranes. Thus, the non-limiting examples of dimensions described above with respect to membrane 514 may apply for each of the membranes 704a-704d.

As shown, at least two of the membranes (e.g., membranes 704a and 704d) may have differing thicknesses, and may furthermore have differing areas, although not all embodiments are limited in this respect. The differing thicknesses may result in the membranes exhibiting different vibratory characteristics, which may lead to differing behavior of mechanical resonating structures formed from the different membranes. Thus, the thickness of each membrane may be selected to provide desired vibratory characteristics, and the differences in thickness may therefore depend on the differences in desired vibratory characteristics. According to one embodiment, a thickness of one membrane may differ from a thickness of a second membrane by between approximately 1 micron and 20 microns (e.g., 2 microns, 5 microns, 10 microns, etc.). According to another embodiment, a thickness difference of two membranes may be between approximately 1 micron and 10 microns, and according to a further embodiment the difference may be between approximately 3 and 10 microns. However, it should be appreciated that other difference values may alternatively be used and that those listed are non-limiting examples.

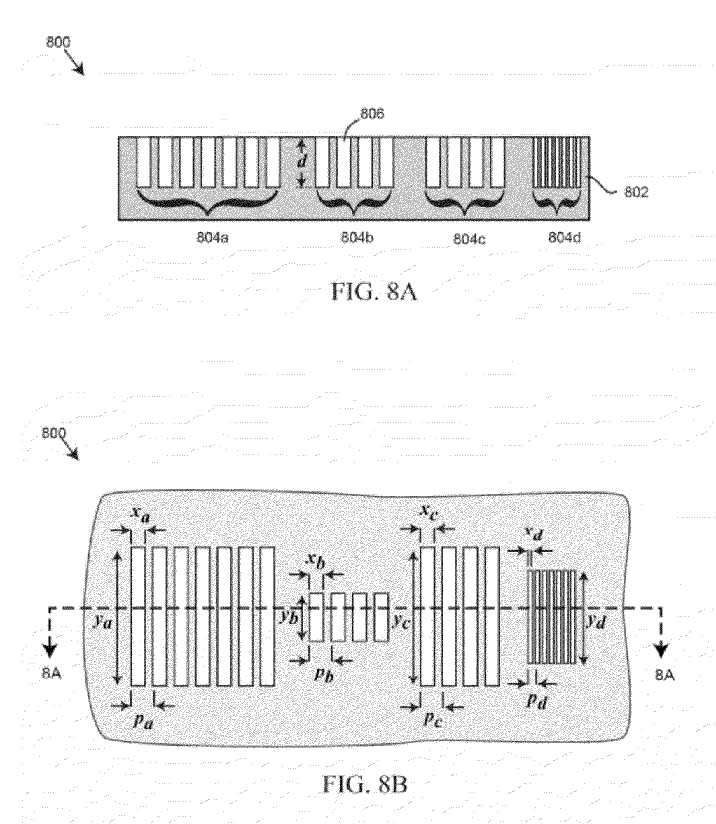

An apparatus including multiple silicon membranes of differing thicknesses, such as apparatus 700 of FIG. 7, may be formed by annealing suitable trench patterns in a substrate (e.g., a silicon substrate). Thus, according to one aspect of the technology, an apparatus includes a substrate with a plurality of trench patterns formed therein, suitable for subsequent annealing to form a corresponding plurality of membranes of different thicknesses. The shape(s) and size(s) (including thickness) of the membranes may be controlled by suitable design of the corresponding trench patterns, including the area of the openings of the trenches, the depth of the trenches, the aspect ratios of the trenches, the shape(s) of the openings of the trenches, and/or the pitch between trenches. Thus, according to the present aspect, the plurality of trench patterns on the substrate may differ in one or more of these trench parameters to produce membranes of different thicknesses. According to one embodiment, the trench patterns may be one dimensional trench patterns comprising a plurality of trenches. A non-limiting example is illustrated in FIGS. 8A (cross section) and 8B (top view).

As shown, the apparatus 800 in this non-limiting example includes a substrate 802 (e.g., a silicon substrate or any other type of substrate described herein) with four distinct trench patterns, 804a-804d, each of which is a one dimensional trench pattern (as will be seen and described further with respect to FIG. 8B) and each of which may be used to form a membrane. Each of the patterns may be characterized by a number of trenches 806, the depth of the trenches of the pattern, the area of the openings of the trenches of the pattern (shown in FIG. 8B), the aspect ratio of the trenches of the pattern (i.e., the ratio of the depth of the trench to the width of the opening of the trench), the shape of the openings of the trenches, and the pitch of the patterns. The patterns may differ in any one or more of these parameters as suitable to create a resulting membrane of a differing thickness. In general, the greater the depth of the trenches, the thicker the membrane; the smaller the aspect ratio of the trenches, the thinner the membrane; the greater the area of the trench openings, the thinner the membrane; and the greater the pitch, the thicker the membrane. However, it should be appreciated that these are general guidelines, and that suitable selection of the combination of the these factors may be used to produce a membrane of a desired thickness.

In the non-limiting example of FIGS. 8A and 8B, pattern 804a includes seven trenches, patterns 804b and 804c each include four trenches, and pattern 804d includes seven trenches. However, other numbers of trenches may be used, and in some embodiments each pattern may have the same number of trenches.

In the non-limiting example of FIGS. 8A and 8B, the trenches of each pattern have the same depth d. However, it should be appreciated that not all embodiments are limited in this respect, as using patterns with trenches of different depths is one way in which membranes of different thicknesses may be formed. In addition, it is not necessary for all the trenches of a pattern (e.g., all the trenches of pattern 804a) to have the same depth as each other. According to one embodiment, trenches within a pattern may have different depths.

As shown in FIG. 8B, the area of the openings of the trenches of the various trench patterns may differ. For example, as shown, the area of the openings of the trenches of pattern 804a (i.e., the area defined by xₐ×yₐ) may differ from the area of the openings of the trenches of pattern 804d (i.e., the area defined by x_{d}×y_{d}). The pitches may also differ (e.g., the pitch pₐ may differ from one or more of p_{b}, p_{c}, and p_{d}). Also, according to some embodiments, the trenches of a trench pattern need not all be separated by the same pitch. For example, some of the trenches may be closer together than others within the pattern (i.e., a pattern need not be characterized by a single pitch). Other variations are also possible.

According to one embodiment, multiple one-dimensional trench patterns are formed in a substrate, with each being suitable to form a membrane. At least some trenches of a first pattern have a first opening area and a first depth. At least some of the trenches of the first pattern are spaced by a first pitch. At least some trenches of a second pattern have a second opening area and a second depth, and at least some of the trenches of the second pattern are spaced by a second pitch. According to one embodiment, at least one of the following conditions is met: (a) the first depth differs from the second depth; (b) the first opening area differs from the second opening area; and (c) the first pitch differs from the second pitch.

Thus, it should be appreciated that FIGS. 8A and 8B provide a non-limiting example of a substrate including four one-dimensional trench patterns from which four membranes may be formed, and that variations are possible. The various parameters of the trenches, including the area of the openings, the depth, and therefore the aspect ratios of the trenches, as well as the pitch of the trenches within each pattern may be selected to provide a desired membrane thickness.

As can be seen from FIG. 8B, each of the patterns 804a-804d is a one dimensional pattern of a plurality of trenches, even though the trenches themselves are obviously not one dimensional. The patterns are one-dimensional in that the trenches of the patterns are arranged in a single dimension (i.e., the x-dimension in this example), as opposed to having multiple trenches in two dimensions (i.e., in both the x and y dimensions, as would be true of an array). Such one dimensional patterns may allow for the use of relatively simple masks for forming the trenches. It should be appreciated, however, that the various embodiments in which membranes are formed are not limited to forming the membranes using one dimensional trench patterns. For example, two-dimensional trench patterns may be used in some embodiments.

The trenches may be formed using various anisotropic dry etching techniques, including, but not limited to, deep reactive ion etching (DRIE), which is often used in combination with a cyclic passivation deposition (the combination being referred to as Bosch process or advanced silicon etch (ASE)). Alternatively, the trenches may also be formed by anisotropic wet etching techniques, including KOH, EDP and TMAH based etch chemistries as well as anodization based etch techniques. Depending on the parameters, i.e. the current density during the anodization process, the silicon might not be completely etched. It should be understood that in some cases the trenches will contain porous silicon residue.

As mentioned, the resulting apparatus (e.g., apparatus 800 of FIG. 8A) may then be annealed to form membranes as shown in FIG. 7. The anneal may be in a hydrogen atmosphere at, for example, 1100° C. and 10 Ton for several minutes. The resulting membranes may be stress free and made of the substrate material (e.g., single crystal silicon).

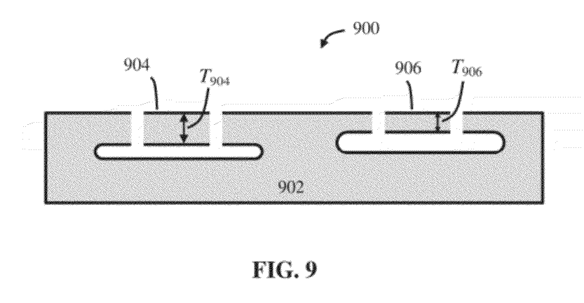

Thus, according to one embodiment, different mechanical resonating structures of a system may be monolithically integrated on the same semiconductor chip using the techniques described above for forming multiple membranes on a semiconductor substrate. As explained, the membranes may be formed with the same or different dimension. According to one embodiment, membranes of different thicknesses may be formed, and may thus be used to form monolithically integrated mechanical resonating structures of different thicknesses. As a non-limiting example, a first membrane may be used to form a gyroscope (e.g., a multi-axis gyroscope, such as a 3-axis gyroscope) while a second membrane may be used to form an accelerometer (e.g., a multi-axis accelerometer, such as a 3-axis accelerometer). Typically, gyroscopes require greater mass than that required for an accelerometer. For instance, a MEMS gyroscope may be on the order of 500 micron thick, while a MEMS accelerometer may be on the order of 100 micron, as non-limiting examples. Thus, according to one non-limiting embodiment, the first membrane may be thicker than the second membrane. Other configurations are also possible. A non-limiting example is shown in FIG. 9.

The device 900 includes two mechanical resonating structures monolithically integrated with a substrate 902 (e.g., a silicon substrate). The mechanical resonating structures 904 and 906 may be formed using the techniques described herein for forming membranes, or may be formed in any other suitable manner. As shown, the mechanical resonating structure 904 may have a thickness T₉₀₄ greater than a thickness T₉₀₆ of the mechanical resonating structure 906. Such differences in thickness may be used for any suitable purpose, for example, to form different mechanical resonating structures have different vibratory characteristics.

A integrated navigation system, such as system 200, in which one or more of the components is integrated (for example, one or more of the mechanical resonating structures is integrated) may provide various benefits. Non-limiting examples of benefits which may be realized according to one or more embodiments include an integrated navigation system that is self-contained and may not need to rely on other external aids. The error rate of the GPS device may be reduced by integration of the INS and the GPS information. The system may provide position, velocity, and/or altitude data in real time at high data rates. The integration of components may allow the system size and power consumption to be reduced compared to conventional systems. Cost reduction may also be achieved. Such benefits may allow the systems to be used in hand-held devices such as cellular phone and GPS systems, consumer electronics (digital cameras, gaming consoles, smart phones, household appliances), robots, automobiles (e.g., for ride stabilization and roll over detection), space and military applications, and aerospace and navigations systems, among others. The integration of components of the system may also enhance the system's robustness.

As has been explained above, according to some embodiments multiple structures (e.g., multiple MEMS structures, such as multiple mechanical resonating structures) may be formed on a single substrate. In some instances, the substrate may include circuitry coupled to the structures, for example drive and sense circuitry coupled to a mechanical resonating structure configured as an oscillator. According to some embodiments, a substrate or wafer including multiple mechanical resonating structures, which may be referred to as a “device wafer”, may be bonded to another substrate or wafer acting as a cover (also referred to herein as a cap). In some such embodiments, the cap wafer may include circuitry (e.g., integrated circuitry) that is coupled to the mechanical structures on the device wafer. In some embodiments, a MEMS wafer includes multiple mechanical resonating structures and a cap wafer that includes integrated circuitry to control the mechanical resonating structures is bonded to the MEMS wafer. Non-limiting suitable configurations and processes for bonding a device wafer to a cap wafer (e.g., for forming capped wafers, including processes for wafer-level packaging techniques and IC-to-MEMS bonding) have been described, for example, in: U.S. patent application Ser. No. 12/750,768, filed Mar. 31, 2010 under Attorney Docket No. G0766.70009US01, entitled “Integration of Piezoelectric Materials with Substrates” and published as U.S. Patent Publication No. 2010-0301703; U.S. patent application Ser. No. 12/899,447, filed Oct. 6, 2010 under Attorney Docket No. G0766.70026US00, and entitled “Integration of Piezoelectric Materials with Substrates”; and U.S. Patent Application Publication No. 2009-0243747, all of which are incorporated herein by reference in their entireties.

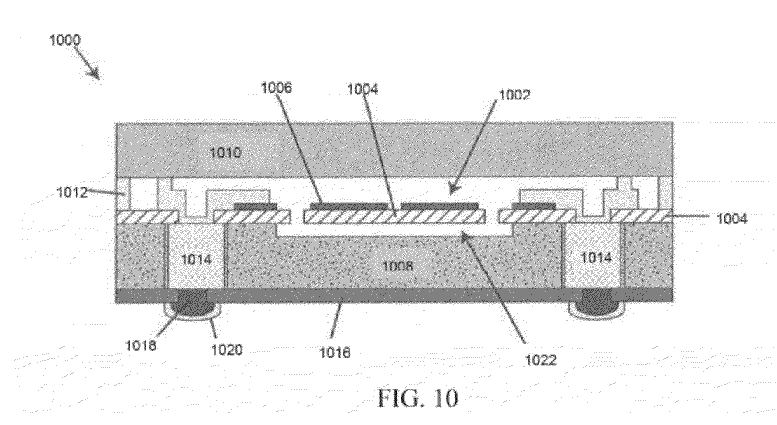

A non-limiting example of a device wafer bonded to a cap wafer is now explained with respect to FIG. 10. For simplicity, only a single mechanical resonating structure is shown on the device wafer. However, it should be appreciated that the wafer may include multiple, and in some cases many, resonating structures, and thus that the illustrated configuration may also be applied to those embodiments described herein in which multiple mechanical resonating structures are on a substrate (e.g., the embodiment of FIG. 9).

FIG. 10 illustrates a cross-sectional view of a non-limiting example of a device 1000 including a device wafer bonded to a cap wafer. As shown, the device 1000 comprises a mechanical resonating structure 1002 which may be formed of a piezoelectric material 1004 and may include one or more electrodes 1006. The piezoelectric material 1004 may comprise quartz, single crystal quartz, or any other suitable piezoelectric material (e.g., aluminum nitride (AlN), zinc oxide (ZnO), cadmium sulfide (CdS), lead titanate (PbTiO₃), lead zirconate titanate (PZT), lithium niobate (LiNbO₃), lithium tantalate (LiTaO₃), potassium niobate (KNbO₃), Li₂B₄O₇, langasite (La₃Ga₅SiO₁₄), gallium arsenide (GaAs), barium sodium niobate, bismuth germanium oxide, indium arsenide, indium antimonide, or any other non-centrosymmetric material), either in substantially pure form or in combination with one or more additional materials. It may be integrated with a substrate 1008, for example by bonding, or in any other suitable manner, for example to form an engineered substrate (or a device wafer). In the non-limiting example of FIG. 10, the substrate 1008 has a cavity 1022 formed therein, above which the mechanical resonating structure 1002 is suspended. However, other configurations are also possible.

The mechanical resonating structure 1002 may be any type of mechanical resonating structure, such as any of those types previously described herein. According to some embodiments, the mechanical resonating structure 1002 may be piezoelectrically actuated using resonant modes that do not require vacuum. These modes may have minimal, or no, out of plane movement that would be damped by the presence of gas pressure so no cavity is required in a wafer that is stacked above the device (MEMS) wafer. Because such mechanical resonating structures can function in a clean air environment and do not require an etched cavity cap, any wafer containing such mechanical resonating structures may be bonded directly to other wafers such as complementary metal oxide semiconductor (CMOS) wafers to create ultra-small form factor, low cost MEMS devices. Thus, according to some embodiments, the substrate 1008 may be attached to a CMOS wafer. The resulting devices may be very thin and have high yields.

In general, the attachment of the device wafer to a cap wafer may be done in any suitable manner, for example using a eutectic bond. This bond can be done with commonly available metals such as gold, tin, aluminum, copper, molybdenum, nickel, germanium or combinations of the aforementioned. This metal can also be used to create interconnects amongst and between the die. It can also be used to create metal structures such as high-Q inductors. Through silicon vias can be used in either wafer (the device wafer or cap wafer) to route the signal out of the device. The types of wafers which may be used as cap wafers can include a CMOS IC wafer, SiGe BiCMOS wafer, Gallium Arsenide wafer or others.

In general, the techniques described herein can be used to create many MEMS devices such as oscillators, radio frequency (RF) filters, gyroscopes, accelerometers, pressure sensors and switches. MEMS devices have been described, for example, in U.S. Patent Application Publication No. US-2009-0267699, entitled “Timing Oscillators and Related Methods”, U.S. patent application Ser. No. 12/830,056, entitled “Methods and Apparatus for Tuning Devices Having Resonators”, filed Jul. 2, 2010, and U.S. Patent Application Ser. No. Ser. No. 61/363,759, entitled “Methods and Apparatus for Calibration and Temperature Compensation of Oscillators Having Mechanical Resonators”, filed Jul. 13, 2010, all of which are incorporated herein by reference in their entireties.

Returning to FIG. 10, the device 1000 further comprises a cap 1010. The cap 1010 may facilitate formation of a hermetic seal (creating either an inert or non-inert environment) for the mechanical resonating structure 1002, or may serve any other suitable purpose. For example, the cap may be bonded to the substrate and/or the piezoelectric material, as described below, to form a vacuum environment for the mechanical resonating structure. However, not all hermetic seals necessarily result in creation of a vacuum environment, and in some embodiments a vacuum environment is not created, as explained above. According to some non-limiting embodiments, circuitry (e.g., integrated circuitry, such as CMOS circuitry, biCMOS circuitry, InP circuitry, etc.) may be formed on the cap 1010, which circuitry may be coupled to the mechanical resonating structure 1002 (e.g., to the electrode 1006 of the mechanical resonating structure 1002) to communicate with the mechanical resonating structure 1002. Thus, according to one non-limiting embodiment, the cap 1010 may be a complementary metal oxide semiconductor (CMOS) cap, with integrated circuitry formed thereon. In FIG. 10, the cap 1010 is bonded to the substrate 1008 and piezoelectric material 1004 by a metallization layer 1012. However, other manners of bonding the cap 1010 to the other components of the device 1000 may be utilized, and other types of bonding materials (e.g., other than metal) may be used.

As mentioned, mechanical resonating structures or other components according to the aspects described herein may be coupled to circuitry (e.g., integrated circuitry) on the substrate(s). The circuitry may control operation of the structures (e.g., may actuate a piezoelectric material structure), may detect operation of the structures (e.g., may detect vibration of the mechanical resonating structure 1002), may process input and output signals sent to/from the structures, or may perform any other suitable functions. In situations in which multiple MEMS structures (e.g., mechanical resonating structures) are formed on a same substrate, each may have its own dedicated circuitry, whether formed on the same substrate as the structures, on a cap wafer, or in any other suitable location. According to one embodiment, multiple mechanical resonating structures are monolithically integrated on a device wafer, and integrated circuitry is also on the device wafer. Alternatively, multiple MEMS structures may share circuitry, whether on the same substrate as the structures, on a cap wafer, or in any other suitable location.

In device 1000, several components provide electrical access to the mechanical resonating structure 1002. Access may be provided to circuitry on the substrate 1008, circuitry on the cap 1010 (if any), and/or circuitry external to the device 1000. For example, in addition to providing bonding, the metallization layer 1012 may also provide electrical connection to the resonating structure 1002, and in particular to the electrode 1006. The metallization layer 1012 may therefore provide an electrical path to circuitry on substrate 1008 and/or circuitry on cap 1010. According to an alternative embodiment, the metallization layer 1012 may operate to provide a hermetic seal, and internal connections (internal to the perimeter of metallization 1012) may be used to provide electrical connection between an IC and a MEMS. According to the non-limiting embodiment of FIG. 10, electrical connection to the mechanical resonating structure 1002 is also provided from a backside of the substrate 1008, by way of two thru-silicon vias 1014 (TSV). The TSVs 1014 may comprise doped silicon having any suitable doping concentration to make the silicon suitably conductive, doped polysilicon with any suitable doping concentration, copper, or any other suitable conductive material. Thus, electrical signals may be sent to/from the mechanical resonating structure 1002 by way of the TSVs, and as such, the TSVs may allow circuits external to the device 1000 to communicate with the mechanical resonating structure 1002. It should be appreciated that any number of such TSVs may be used (e.g., one, two, or many more than two), in those embodiments which utilize TSVs, and that not all embodiments include TSVs. According to some embodiments, the TSVs may function to communicate control and/or detection signals with the mechanical resonating structure 1002. According to some embodiments, control and detection of the mechanical resonating structure may be substantially performed by circuits on the substrate 1008 and/or cap 1010, and only processed signals (e.g., output signals) may be sent external to the device 1000 by the TSVs. Other communication schemes are also possible.

The device 1000 further comprises additional layers 1016, 1018, and 1020. Layer 1016 may be an insulation layer (e.g., SiO₂), formed in any suitable manner (e.g., deposition or growth), and etched in any suitable manner for subsequent formation of layers 1018 and 1020. The layers 1018 and 1020 may represent under-bump metallization (UBM) to provide electrical access to the mechanical resonating structure and/or integrated circuitry of device 1000 from the backside of the substrate 1008, and thus may be formed of any suitable materials and in any suitable manner. For example, the layer 1018 may be electroless plated nickel and the layer 1020 may be electroless plated gold, although other materials and methods of formation are also possible.

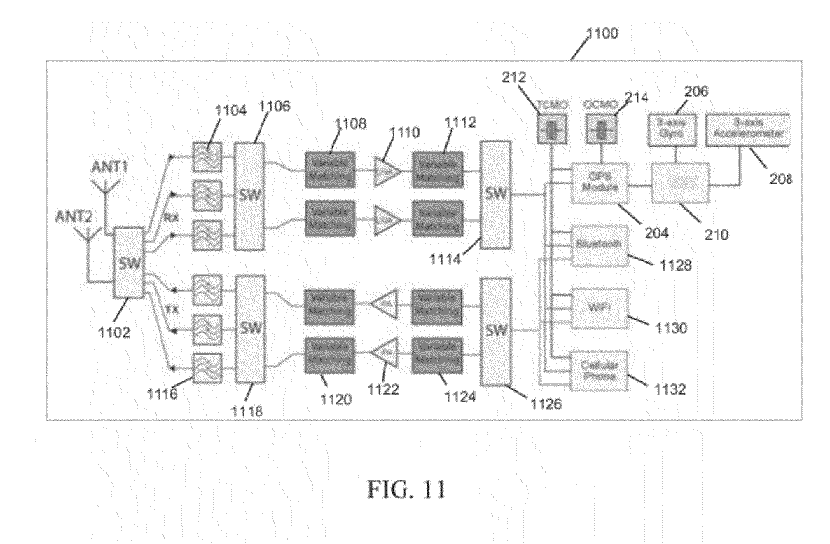

Various non-limiting examples of devices forming an integrated navigation system have been described. However, it should be appreciated that the various aspects described herein are not limited to such devices. For instance, according to one embodiment, an integrated navigation system may form part of a larger device or system. An example is now described in connection with FIG. 11, which shows a transceiver incorporating many of the components of the integrated navigation system 200 of FIG. 2.

A transceiver is a device that has both a transmitter and a receiver which can be combined and share common circuitry. Transceiver functionality (receive and transmit) in each frequency band may require a number of discrete components positioned prior to digitization of the received signal. The number of discrete transceiver components continues to rise as more frequency bands and functionalities are added to transceivers.

Conventional transceiver components are discrete components. Thus, as the number of components continues to rise, the size and complexity of manufacturing transceivers rises as well. According to an aspect of the technology, a transceiver includes one or more MEMS components which are integrated, for instance in the manners previously described herein. Such integration may facilitate space savings and ease of fabrication of a transceiver, and may also improve the robustness of the transceiver.

As shown in FIG. 11, the non-limiting example of a transceiver 1100 according to an embodiment of the present technology includes a receive side and a transmit side. Two antennas ANT1 and ANT2 operate to receive and transmit signals. The receive side (RX) circuitry includes three filters (e.g., band select filters, such as low-pass filters) 1104, a switch 1106 (e.g., an RF switch), variable matching components 1108 (i.e., impedance matching network), low-noise amplifiers 1110, more variable matching components 1112, and a switch 1114 (e.g., an RF switch). The transmit side (TX) circuitry includes a switch 1126 (e.g., an RF switch), variable matching components 1124 (i.e., impedance matching networks), two power amplifiers 1122, additional variable matching components 1120, a switch 1118 (e.g., an RF switch), and three filters 1116 (e.g., band select filters, such as low-pass filters). The transceiver further comprises the 3-axis gyroscope 206, 3-axis accelerometer 208, INS processor 210, TCMO 212, OCMO 214, and GPS module 204 of FIG. 2. In addition, a Bluetooth component 1128, Wi-Fi component 1130, and cellular phone component 1132 are provided.

The transceiver 1100 illustrated in FIG. 11 is a non-limiting example. A combined GPS and INS as shown in FIG. 2 may be used in various types of transceivers, or other systems, and that shown is provided merely for purposes of illustration.

As should be appreciated from the previous discussion of FIG. 2, two or more components of the GPS and INS of transceiver 1100 may be integrated. In addition, other components of the transceiver 1100 may be integrated using the techniques described herein. For instance, many of the transceiver components may be MEMS-based components, such as MEMS switches (e.g., switches 1106, 114, 118, and 1126), filters (e.g., 1104, 1116), impedance matching networks (e.g., 1108, 1112, 1120, 1124), TCMOs (e.g., 212), OCMOs (e.g., 214), gyroscopes (e.g., 206) and accelerometers (e.g., 208). Any two or more of these MEMS components may be integrated on the same chip or may be integrated in a multi-chip module using the techniques described herein or any other suitable techniques.

Thus, it should be appreciated that a transceiver architecture that includes integrated MEMS-based components has been described. The MEMS-based components may be integrated on a single chip. The components may be RF components. Replacement of off-chip discrete components in certain conventional transceiver architectures by on-chip MEMS components may allow for the reduction of system size and power consumption, which may improve functionality, reduce cost and enhance robustness, amongst other advantages.

The mechanical resonating structures described herein may be used as stand-alone components, or may be incorporated into various types of larger devices. Thus, the various structures and methods described herein are not limited to being used in any particular environment or device. However, examples of devices which may incorporate one or more of the structures and/or methods described herein include, but are not limited to, tunable meters, mass sensors, gyroscopes, accelerometers, switches, and electromagnetic fuel sensors. According to some embodiments, the mechanical resonating structures described are integrated in a timing oscillator. Timing oscillators are used in devices including digital clocks, radios, computers, oscilloscopes, signal generators, and cell phones, for example to provide precise clock signals to facilitate synchronization of other processes, such as receiving, processing, and/or transmitting signals. In some embodiments, one or more of the devices described herein may form part or all of a MEMS. The described systems may be used, for example, in the following applications: cellular phone, Wi-Fi, satellite radio and GPS receiver, consumer electronics (e.g., printers, digital cameras, gaming consoles, household appliances), automobile (e.g., ride stabilization and roll over detection), space communication and military applications, navigation and wireless systems.

Having thus described several aspects of at least one embodiment of the technology, it is to be appreciated that various alterations, modifications, and improvements will readily occur to those skilled in the art. Such alterations, modifications, and improvements are intended to be within the spirit and scope of the technology. Accordingly, the foregoing description and drawings provide non-limiting examples only.

In addition, while some references have been incorporated herein by reference, it should be appreciated that the present application controls to the extent the incorporated references are contrary to what is described herein.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A system, comprising:
a global positioning system (GPS) receiver having a first mechanical resonating structure; and
an inertial navigation system (INS) comprising a second mechanical resonating structure,
wherein the first mechanical resonating structure and second mechanical resonating structure are integrated.

2. The system of claim 1, wherein the first mechanical resonating structure and the second mechanical resonating structure are integrated on a single semiconductor substrate.

3. The system of claim 2, wherein the first mechanical resonating structure has a first thickness and wherein the second mechanical resonating structure has a second thickness.

4. The system of claim 2, wherein the first mechanical resonating structure and the second mechanical resonating structure are formed, at least in part, by forming a first membrane in the semiconductor substrate and a second membrane in the semiconductor substrate for the first mechanical resonating structure and the second mechanical resonating structure, respectively.

5. The system of claim 1, wherein the first mechanical resonating structure is formed on a first semiconductor chip and the second mechanical resonating structure is formed on a second semiconductor chip, and wherein the first semiconductor chip and the second semiconductor chip are integrated into a single multi-chip module.

6. The system of claim 1, wherein the second mechanical resonating structure forms at least part of an accelerometer.

7. The system of claim 1, wherein the second mechanical resonating structure forms at least part of a gyroscope.

8. The system of claim 1, wherein one or more of the first mechanical resonating structure and the second mechanical resonating structure is a piezoelectric mechanical resonating structure.

9. The system of claim 8, wherein the first mechanical resonating structure is a piezoelectric mechanical resonating structure, and wherein the first mechanical resonating structure comprises a material selected from the group consisting of: AN, Zno, PZT, LNBO, and LTiO.

10. The system of claim 1, wherein the inertial navigation system comprises a third mechanical resonating structure, and wherein the first, second, and third mechanical resonating structures are integrated.

11. The system of claim 1, wherein the GPS receiver and INS form at least part of a transceiver.

12. The system of claim 11, wherein the transceiver comprises a microelectromechanical (MEMS) switch, and wherein the MEMS switch is integrated with at least the first mechanical resonating structure.

13. The system of claim 12, wherein one or more of the first mechanical resonating structure and the second mechanical resonating structure is a piezoelectric mechanical resonating structure.

14. The system of claim 1, wherein the first and second mechanical resonating structures are MEMS resonators.

15. The system of claim 1, further comprising a processor coupled to the GPS receiver and INS to receive output signals of the GPS receiver and INS and calculate a current location of the system.

16. The system of claim 1, wherein the first mechanical resonating structure is a microelectromechanical (MEMS) resonator configured to provide a reference clock signal for the GPS, wherein the second mechanical resonating structure is a MEMS resonator forming at least part of a multi-axis accelerometer, and
wherein the INS further comprises a third mechanical resonating structure which is a MEMS resonator forming at least part of a multi-axis gyroscope,
wherein the first, second, and third mechanical resonating structures are formed on a single semiconductor chip, and wherein a thickness of the third mechanical resonating structure is greater than a thickness of the second mechanical resonating structure.

17. The system of claim 1, wherein the first mechanical resonating structure is actuated and/or detected using electrostatic and/or piezoelectric and/or magnetic actuation and/or detection.

18. The system of claim 1, wherein the first mechanical resonating structure comprises a silicon layer and a second layer, and wherein the silicon layer and second layer operate in combination to compensate temperature-induced changes in a resonance frequency of the first mechanical resonating structure.
